(19) United States
(12) Patent Application Publication
(10) Pub. No.: US 2024/0120428 A1
(43) Pub. Date: Apr. 11, 2024

(54) HIGH VOLTAGE AND HIGH-POWER DIAMOND BASED JUNCTION-GATE FIELD EFFECT TRANSISTOR (JFET) SWITCH WITH PHOTO-CONTROLLED GATE

(71) Applicant: Lawrence Livermore National Security, LLC, Livermore, CA (US)

(72) Inventors: Qinghui Shao, Fremont, CA (US); Lars F. Voss, Livermore, CA (US)

(21) Appl. No.: 18/480,996

(22) Filed: Oct. 4, 2023

Related U.S. Application Data
(60) Provisional application No. 63/378,393, filed on Oct. 5, 2022.

(51) Int. Cl. H01L 31/112; H01L 31/0216; H01L 31/028

(52) U.S. Cl. CPC H01L 31/1126; H01L 31/02164; H01L 31/028; H01L 29/1602

(57) ABSTRACT

Devices, methods and techniques related to high voltage and high-power diamond transistors are disclosed. In one example aspect, a switch operable under high-voltage and high-power includes a P-type diamond layer doped with an acceptor material, a first N-type diamond layer doped with a donor material and in contact with one side of the P-type diamond layer, a light blocking layer comprising the one or more apertures configured to allow the light to enter the first N-type diamond layer, a source contact and a drain contact that are at least partially in contact with the P-type diamond layer, and the gate in contact with at least an area of the first N-type diamond layer that corresponds to one of the one or more apertures. The gate can be positioned on the backside of the substrate.

### CROSS-REFERENCE TO RELATED APPLICATION(S)

This patent document claims the benefit of priority to U.S. Provisional Patent Application No. 63/378,393, filed on Oct. 5, 2022. The contents of the above-noted application are incorporated herein by reference in its entirety.

### FEDERALLY SPONSORED RESEARCH OR DEVELOPMENT

This invention was made with Government support under Contract No. DE-AC52-07NA27344 awarded by the United States Department of Energy. The Government has certain rights in the invention.

### TECHNICAL FIELD

This document generally relates to transistors, and particularly to high voltage and high-power diamond transistors.

### BACKGROUND

The power electronics systems ranging from kilowatts to gigawatts of power with high efficiency are in need for energy conversion.

### BRIEF DESCRIPTION OF THE DRAWINGS

FIG. 1 is a schematic diagram of an example diamond Junction-gate Field Effect Transistor (JFET) switch in accordance with one or more embodiments of the present technology.

FIG. 2 is another schematic illustration of an example diamond JFET switch in accordance with one or more embodiments of the present technology.

FIG. 3 illustrates an example plot of drain current varying with different substrate voltages in accordance with one or more embodiments of the present technology.

FIG. 4 illustrates an example drain current and substrate current with respect to different substrate voltages in accordance with one or more embodiments of the present technology.

FIG. 5A illustrates a temporal change of light intensity and substrate voltage in accordance with one or more embodiments of the present technology.

FIG. 5B illustrates a temporal change of a drain current corresponding to the light intensity and substrate voltage in FIG. 5A.

FIG. 6A illustrates an example hole concentration profile at T=10 ms corresponding to FIGS. 5A-B in accordance with one or more embodiments of the present technology.

FIG. 6B illustrates an example hole concentration profile at T=20 ms corresponding to FIGS. 5A-B in accordance with one or more embodiments of the present technology.

FIG. 6C illustrates an example hole concentration profile at T=30 ms corresponding to FIGS. 5A-B in accordance with one or more embodiments of the present technology.

FIG. 6D illustrates an example hole concentration profile at T=40 ms corresponding to FIGS. 5A-B in accordance with one or more embodiments of the present technology.

FIG. 6E illustrates an example hole concentration profile at T=50 ms corresponding to FIGS. 5A-B in accordance with one or more embodiments of the present technology.

FIG. 6F illustrates an example hole concentration profile at T=70 ms corresponding to FIGS. 5A-B in accordance with one or more embodiments of the present technology.

FIG. 7 is a flowchart representation of an example procedure to operate a switch device in accordance with one or more embodiments of the present technology.

FIG. 8 illustrates simulation results of 5 um and 10 um channel diamond JFET together with GaN and diamond limits in the plot of Baliga's Figures of Merit (FOM).

FIG. 9 illustrates an example diamond JFET with multiple apertures as junction termination extensions in accordance with one or more embodiments of the present technology.

FIG. 10 illustrates another example diamond JFET with multiple apertures as junction termination extensions in accordance with one or more embodiments of the present technology.

FIG. 11 illustrates yet another example diamond JFET with multiple apertures as junction termination extensions in accordance with one or more embodiments of the present technology.

### DETAILED DESCRIPTION

Due to diamond's high thermal conductivity (22 W/cmK), high hole mobility (>2000 cm2/Vs), and high critical electric field (>10 MV/cm), diamond has overwhelming advantages over silicon and other wide bandgap materials (e.g., 4H-SiC, GaN, GaO and AlN) for ultra-high-voltage and high-temperature applications. Recent developments have demonstrated the availability of relative low cost and low dislocation density (e.g., 10⁵ cm⁻²) of high pressure high temperature (HPHT) substrates. High quality of p-type diamond layer by chemical vapor deposition is also available. However, the material has not yet delivered the expected high performance, mainly due to the absence of shallow donor and acceptor impurities. For example, one of the well investigated donors is nitrogen that has an activation energy of 1.7 eV. The acceptor can be boron having an activation energy of 0.38 eV. At room temperature, the deep donors offer no free electrons even at high doping levels (e.g., 10¹⁸ to 10¹⁹ cm⁻³): only 6×10¹⁴ cm⁻³ free hole concentration is available with 2×10¹⁷ cm³ net doped boron. High-temperature (HT) operation using the material may alleviate the issue of the incomplete ionization of dopant species but can also result in severe thermal management issues and affect the overall stability and long-term reliability.

This patent document, among other features, discloses techniques that can be implemented in various embodiments to optically activate the deep donors (also referred to as impurities) to enable a viable route for diamond transistors in high voltage switch applications. The disclosed techniques can be particularly suitable for JFETs. It is noted that the discussions below focus on using nitrogen as the deep donor and boron as the acceptor. The disclosed techniques, however, are also applicable to other donor/acceptor materials suitable for diamond layers. For example, donors in diamond can be Nitrogen, Phosphorus, Oxygen and their complexes. The acceptors can be boron, and its complexes.

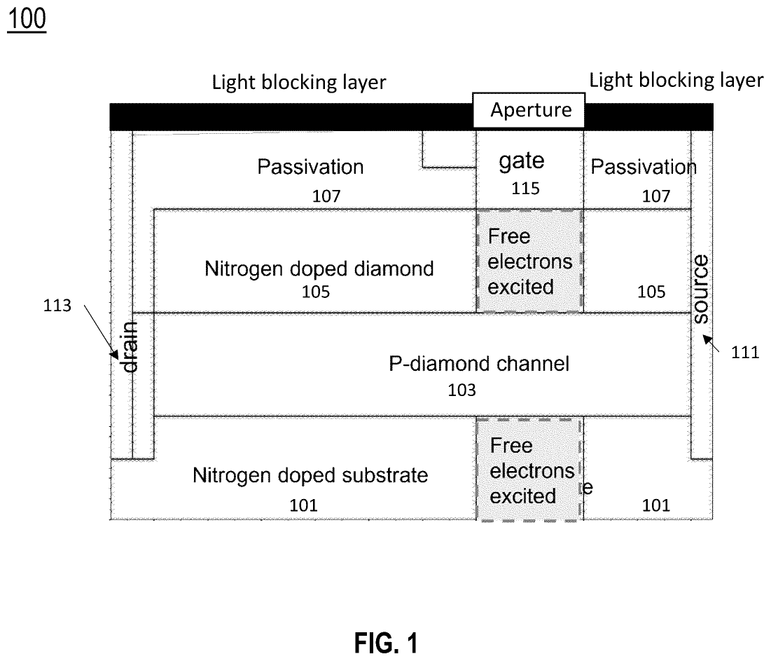

FIG. 1 is a schematic illustration of an example diamond JFET switch 100 in accordance with one or more embodiments of the present technology. As illustrates in FIG. 1, a nitrogen doped N-type diamond substrate 101 is provided. The doping level can be in the 10¹⁹ cm⁻³ range with 1.7 eV ionization energy. A P-type boron-doped diamond layer 103 can be epitaxially grown on top of the nitrogen doped N-type substrate. In some embodiments, the P-type boron-doped diamond layer 103 can have a thickness of around of 0.5 um (e.g., between 0.1 um to 1 um) with an ionization energy of around 0.38 eV. Another nitrogen doped N-type diamond layer 105 can be epitaxially grown on top of the boron-doped P-type diamond layer 103. The thickness of the nitrogen doped diamond layer 105 can also be around 0.5 um.

In some embodiments, in addition to the nitrogen and boron doped layers, a dielectric passivation layer 107 can be deposited on top of the nitrogen doped N-type diamond layer 105. The source 111 and drain 113 contacts can be formed by etching through the passivation layer 107, the nitrogen doped diamond N-type layers (101, 105), and the boron-doped diamond P-type layer 103, followed by metal deposition. The gate contact 115 can be formed by etching through the passivation layer 107 and by deposition of transparent conductive gate such as indium-tin-oxide (ITO) film to contact the nitrogen doped diamond N-type layer 105 A light blocking layer is deposited on top of the passivation layer. The light blocking layer can comprise any materials that reflects or blocks light (e.g., aluminum). An aperture (e.g., having a width of around 2 μm) is provided from the top (e.g., by etching at least part of the light blocking layer). When light from a light source provides illumination through the aperture, the light goes through the passivation and P-type layer 103 without absorption, because there is no deep donor presence. However, the light that reaches the N-type layer 105 and N-type substrate 101 gets absorbed. The free electrons can be photo-excited from deep donors to conduction band. The photon energy of the light needs to be higher than the activation energy of the doping material (e.g., nitrogen at 1.7 eV) and the wavelength of the light needs to be appropriate for absorption based on the doping material. In this specific example, the threshold wavelength is around 730 nm. The wavelength is preferably shorter than the threshold wavelength as light having a longer wavelength may not be effectively absorbed. The conduction p-channel can then be modulated by changing the gate voltage.

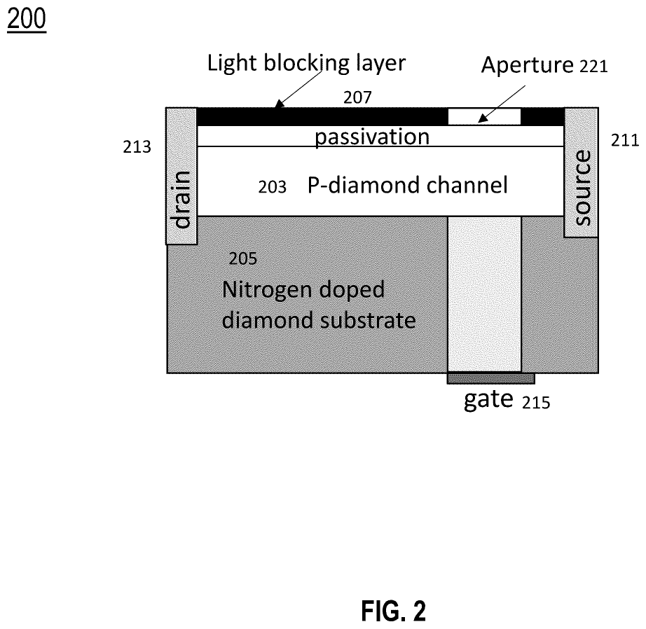

In some embodiments, to ease the difficulty of epitaxial growth of n-diamond layers on top of p-diamond layer, an example diamond JFET switch 200 is schematically illustrated in FIG. 2. In this example, the nitrogen doped substrate 205 having a thickness of 100-500 μm is in use. The boron-doped P-type layer 203 is deposited on top of the N-type substrate 205. The thickness of the P-type layer 203 can be 0.1 μm to 1 μm, or even at the mm level. In some embodiments, a passivation layer can be deposited on top of the P-type layer 203. Drain contact 213 and source contact 211 are deposited in contact with P-type diamond layer after etching through of passivation and P-diamond layer. Gate contact 215 is formed by metal deposition on the backside of the substrate 205. A light blocking layer 207 is deposited on the passivation layer. The light blocking layer 207 can comprise any materials that reflects or blocks light (e.g., aluminum). An aperture 221 (e.g., having a width of around 2 μm) is provided from the top (e.g., by etching at least part of the light blocking layer 207). When light from a light source provides illumination through the aperture, the light goes through the passivation layer and P-type layer 203 without absorption. The light reaches the N-type substrate 205 and the free electrons can be photo-excited in the illuminated region. The gate voltage on the back is transferred to P-type channel and modulates the current conduction.

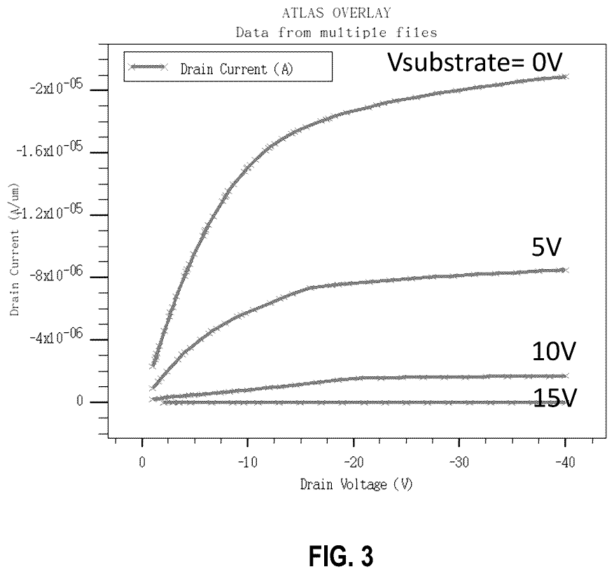

FIG. 3 illustrates example plots of drain current versus drain voltage for different substrate voltages (also referred to as gate voltages) in accordance with one or more embodiments of the present technology. In this example, the light from the light source has a wavelength of 550 nm and a power of 11 W/cm². When the substrate/gate voltage is set to 0V, there is a steady build-up of the conduction current between the source and the drain ( ). When the substrate/gate voltage is increased, the current between the source and the drain is gradually decreased. At 15V, for example, the current between the source and the drain is totally blocked. The desired conduction current (ON state) can be tuned by varying the substrate/gate voltage. Once it is reached, the light can be turned off and the substrate/gate voltage can be turned off. The switch can memorize the current channel condition and the electric current remains conducting. The portion of the N-layer(s) without light activation remains semi-insulating.

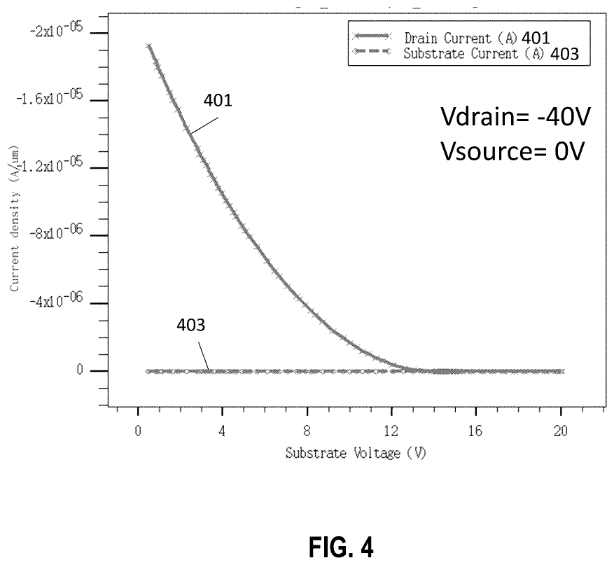

The current can be depleted again by tuning up the substrate/gate voltage. FIG. 4 illustrates example plots of drain current and substrate/gate current versus substrate/gate voltage with a certain drain-source voltage of −40V in accordance with one or more embodiments of the present technology. As shown in FIG. 4, the drain current 401 reduces as the substrate (gate) voltage increases, and the substrate (gate) current 403 remains at a very low level (e.g., close to 1×10⁻¹¹ A/μm). The layer(s) can be fully depleted at around 13V substrate (gate) voltage.

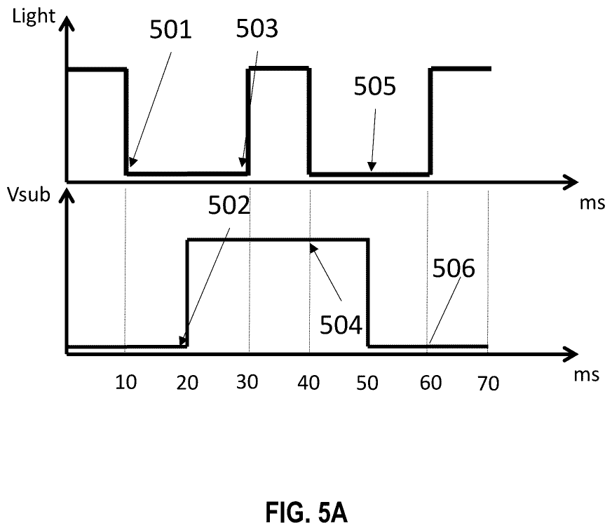

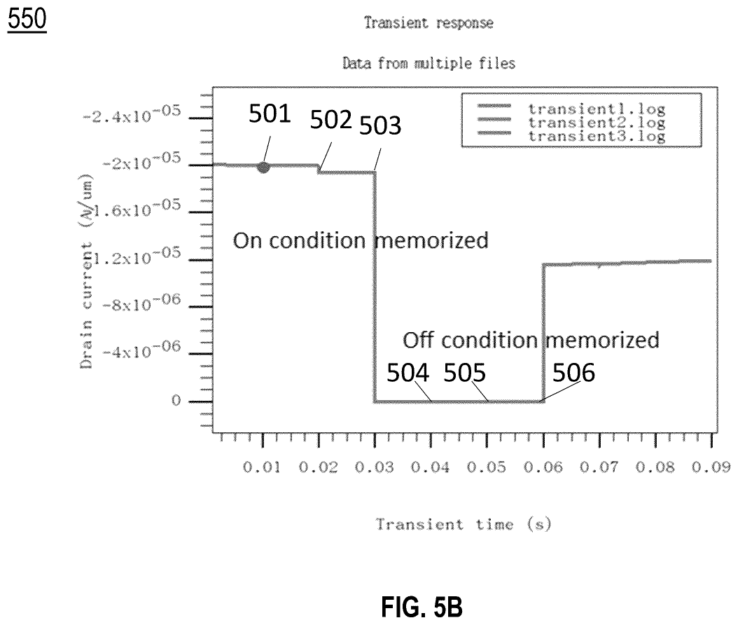

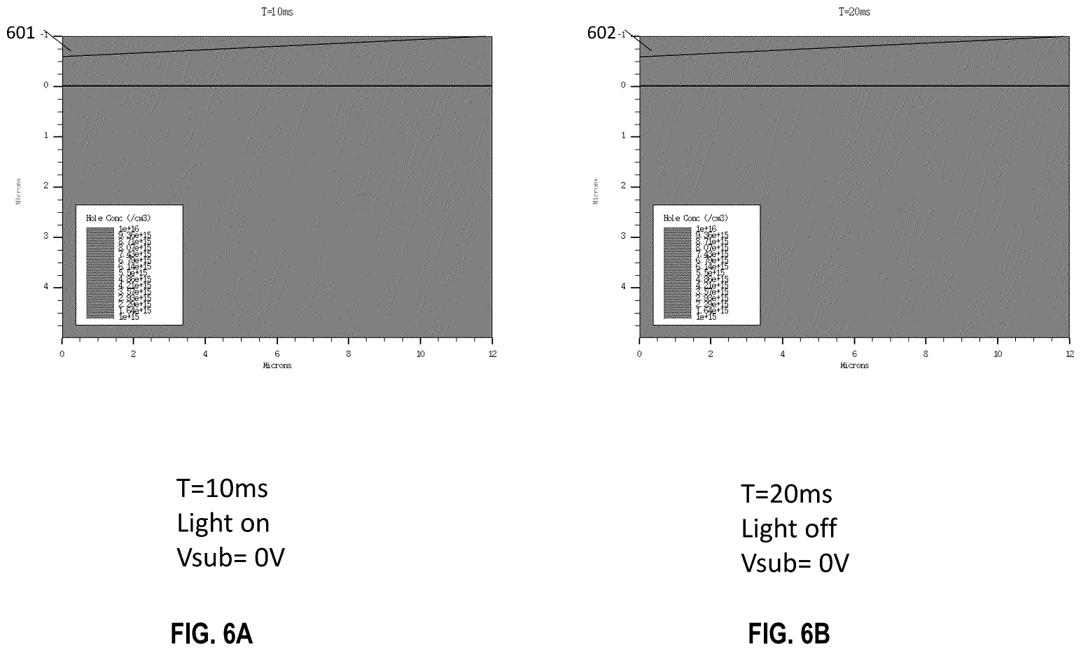

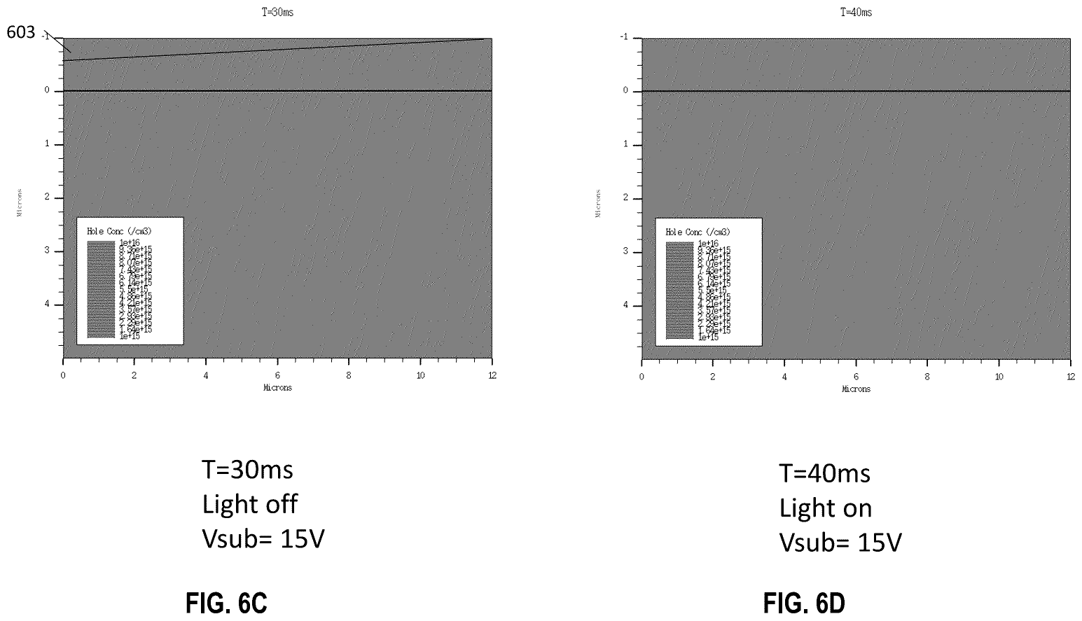

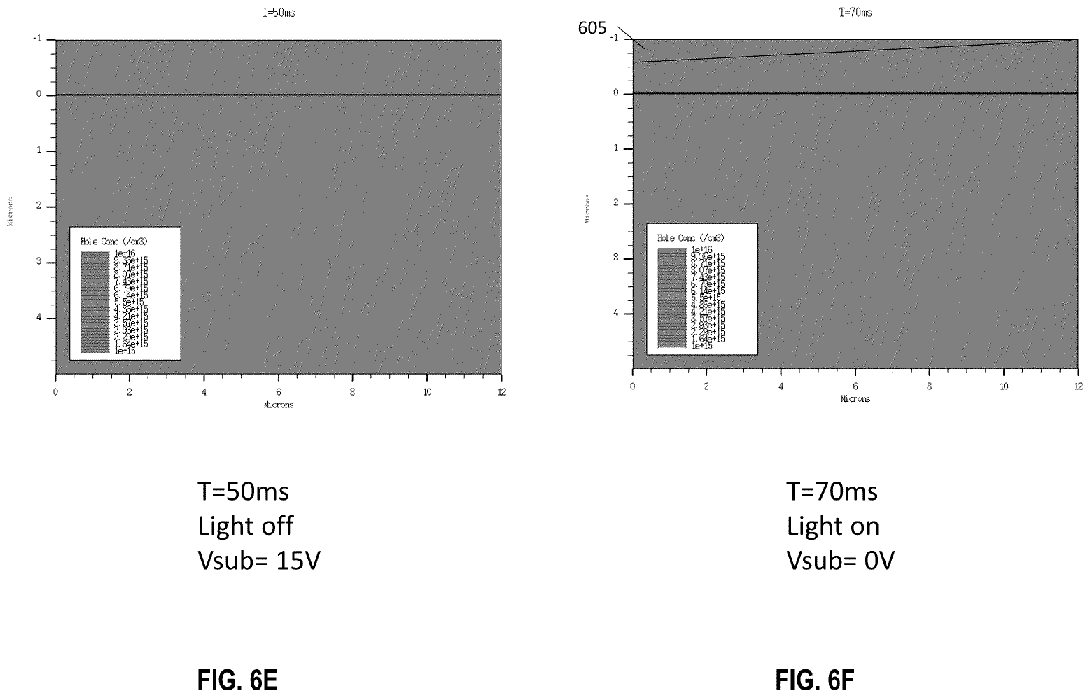

Turning on or off a switch device implemented using the disclosed techniques does not require the continuous application of the light or the substrate/gate voltage. Once in a particular state (e.g., on or off), the conduction channel between the source and the drain of the switch device can be “locked” such that the switch device can memorize its state for a prolonged period of time. The prolonged period of time is determined based on the material properties (e.g., RC delay and/or resistance) and can last minutes, hours, or even days. The temporal change of light intensity, substrate (gate) voltage, and the conduction current between the source and the drain are further illustrated in FIGS. 5A-5B and 6A-6F. The time instances, T=10 ms, 20 ms, 30 ms, 40 ms, 50 ms, and 60 ms, when different actions take place, are labeled as 501, 502, 503, 504, 505, and 506 in FIGS. 5A-6F.

As shown in 5A and 6A, prior to T=10 ms (501), the switch device can be turned on by switching the light source on and setting the substrate/gate voltage Vsub to 0V. A conduction current can be produced between the source and the drain (as shown in FIG. 5B and FIG. 6A). The conduction current in FIG. 6A is illustrated by the expanded area of high hole concentration labeled as 601. Similar labeling convention is used in FIGS. 6B-6F. At T=20 ms (502), as shown in FIG. 5A, the light source can be switched off without impacting the on-state of the switch device. The substrate (gate) voltage can remain to be 0V. The device can memorize the ON condition and there remains a conduction current 602 between the source and the drain (as shown in FIG. 5B and FIG. 6B). At this point, a change of substrate/gate voltage may not change its conduction current. For example, at T=30 ms (503), the substrate/gate voltage has ramped up to 15V and held for 10 ms, there is no conduction current change as shown in FIG. 5B

The switch device can be changed to be in the OFF state by switching the light source on and setting the substrate/gate voltage Vsub to 15V. For example, at T=30 ms (503), the device is still in the ON state, having a conduction current 603 between the source and the drain with a substrate/gate voltage of 15V (as shown in FIG. 5B and FIG. 6C). After switching the light source on, the switch device turns into the OFF state at T=40 ms (504) (as shown in FIG. 5B and FIG. 6D). By keeping the light off, the device can also memorize the OFF state (as shown in FIG. 5B). When the substrate/gate voltage Vsub is changed to 0V at T=50 ms, the conduction current remains to be low (as shown in FIG. 5B and FIG. 6E) and the device remains off. The device can be turned back on again by switching the light after T=60 ms (506) with substrate voltage Vsub being 0V. As shown in FIG. 6F, a conduction current 605 is again established at T=70 ms.

Due to the “locking” or memorization properties of the switch device, the light that is applied can be a pulse to reduce cost and energy consumption. For example, a light pulse having a short cycle time between 1 to 10 μs (e.g., 4 μs at 250 kHz frequency) can be used to promptly turn on (activate) and off (reactive) the switch device. The cycle time and/or frequency of the pulse light can be determined by the carrier life time of the doping material(s) and/or the N-type substrate thickness. The substrate/gate voltage can also be pulsed. The shortest cycle time and/or maximum frequency of the pulsed voltage can be in the same range of light pulse.

As mentioned above, the deep donor with 2×10¹⁷ cm⁻³ net doped boron can offer only 6×10¹⁴ cm⁻³ free hole concentration at room temperature. In some applications, it may be desirable to increase the hole concentration to reduce the on resistance. To achieve this, a second light source can be switched on to excite free holes. The desired wavelength of the second light source can be longer than the first light source such that the photon energy of the second light is greater than the activation energy of boron but smaller than the activation energy of nitrogen. The channel conductivity is linearly proportional to the light intensity, and a shorter wavelength is preferred to achieve higher absorption coefficient. In some embodiments, the free hole concentration can be increased by two orders of magnitude depending on the acceptor optical cross section and the intensity of the second light. Unlike the first light source, however, the second light source needs to remain on to maintain the elevated conduction current. Therefore, usage of the second light source can be suitable for short duty-cycle applications.

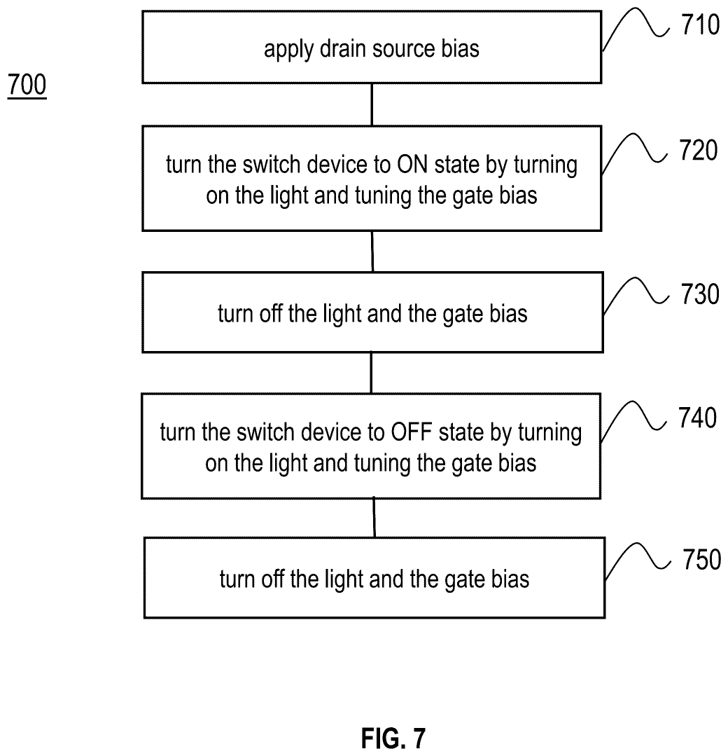

FIG. 7 is a flowchart representation of an example procedure 700 to operate a switch device in accordance with one or more embodiments of the present technology. The procedure 700 includes the following operations:

Operation 710: Apply an appropriate drain-to-source bias voltage.

Operation 720: Turn on the first light source (also referred to as the gate-control-light) and tune the gate bias (e.g., 0V) to meet desired conduction current so that the switch device is in the ON state.

Operation 730: Turn off the gate-control light and adjust the gate bias down to 0V once the conduction current is maintained. The switch device maintains its ON state.

Operation 740: To turn the switch device into the OFF state, turn on the gate-control light and adjust the gate bias to deplete the channel.

Operation 750: Turn off the gate-control light and adjust the gate bias down to 0V. The channel remains blocked, and the switch device maintains its OFF state.

Operation 720 can be repeated to bring the switch device back to ON state

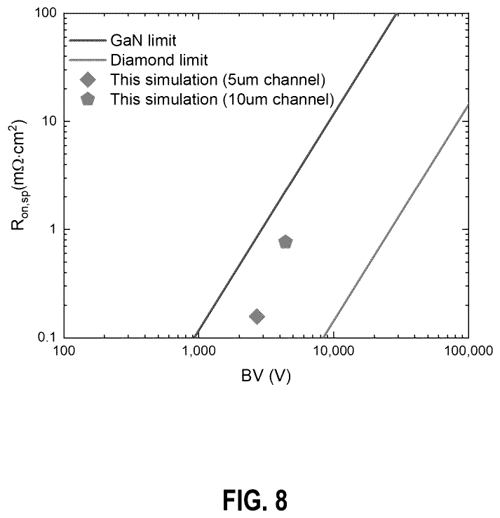

FIG. 8 illustrates simulation results of 5 μm and 10 μm channel diamond JFET together with GaN and diamond limits in the plot of Baliga's Figures of Merit (FOM). The simulated specific on resistance (Ron, sp) and breakdown voltage are 0.157 mΩ-cm², 2700 V for 5 um channel devices and 0.762 mΩ-cm², 4400 V for 10 μm channel devices, respectively. As shown in FIG. 8, the results place the disclosed devices beyond the GaN limit in the plot of Baliga's figure of merit.

In some embodiments, to mitigate a high electric field occurring at the corner of gate and p-type diamond layer interface, the disclosed techniques can be applied to Junction termination extension (JTE) technique. JTE is a technique for increasing avalanche breakdown voltage and controlling surface electric fields in PN junctions. The technology of JTE is widely used in power diodes and transistors to improve the breakdown voltage. Due to the unique lattice structure and extreme material strength, doping depths are limited to 10 nm by means of a high energy ion implantation process in diamond. Combined with low ionization rates of deep dopants, JTEs can be less effective in diamond. The disclosed optical stimulated excitation offers a feasible way to enable the function of JTEs without complicated ion implantation and activation processes. The periodic junction locations and spacings are optically defined by apertures etched in a light blocking layer. The effective electron concentration and conductivity are modulated by incident light intensity.

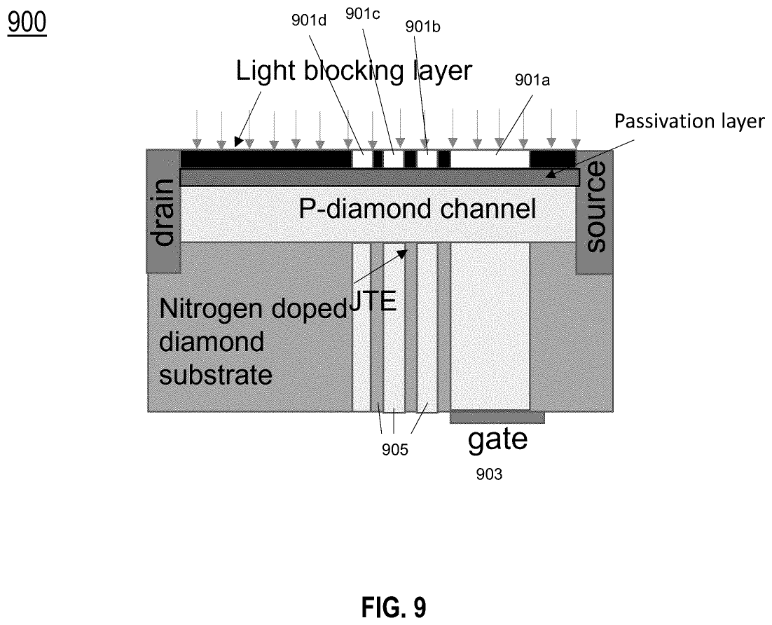

FIGS. 9-11 illustrate three device designs with nitrogen doped diamond substrates as gates. FIG. 9 illustrates an example diamond JFET 900 with multiple apertures as junction termination extensions in accordance with one or more embodiments of the present technology. The light shining through the apertures 901a, 901b, 901c, 901d generates free electrons (shown as light gray regions in FIG. 9). The periodically spaced conductive and resistive features mitigate the local high electric field away from the gate corner. The back gate metal 903 is aligned to the desired gate region avoiding contact with JTEs 905 such that the JTEs do not short to the gate.

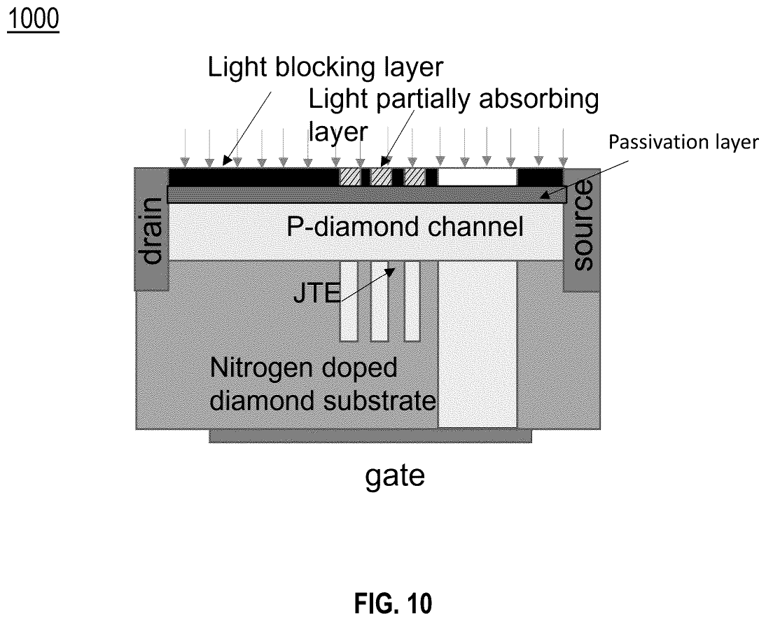

FIG. 10 illustrates another example diamond JFET 1000 with multiple apertures as junction termination extensions in accordance with one or more embodiments of the present technology. In this example, a partially light-absorbing material is filled in the apertures to allow easier alignment of the gate at the bottom. The light that goes through the apertures is partially absorbed, so the generated electron concentration at the back of the substrate is not sufficient to short the gate on the backside (as illustrated by light gray channels that do not reach the bottom of the substrate). The generated electron concentration, however, is high enough at the interface of p-diamond channel to enable the JTEs function in reducing the local high electric fields. In this design, no fine alignment between top to bottom surfaces is required, and a blanket back-gate metal that covers a large section of the backside can be implemented.

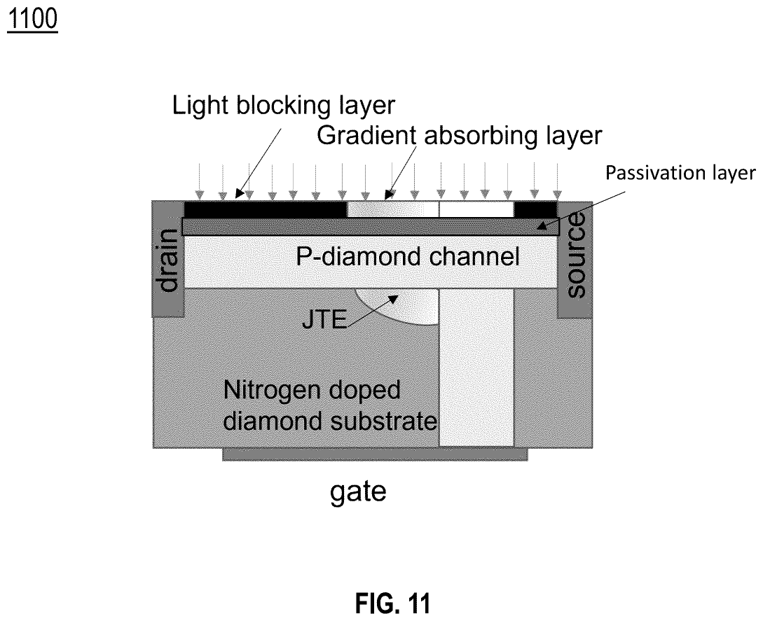

FIG. 11 illustrates yet another example diamond JFET 1100 with multiple apertures as junction termination extensions in accordance with one or more embodiments of the present technology. In this example design, a single aperture is filled with gradually light absorbing (e.g., a gradient index or a gradient thickness) material to gradually absorb the light. A gradient of light intensity is formed at the interface when it propagates through the channel layer. It induces a gradually reduced electron concentration away from the gate position. The layer with gradually changed resistance reduces the local high field and improve the device breakdown voltage. This design does not require fine alignment between top to bottom surfaces either.

Some preferred embodiments according to the disclosed technology adopt the following solutions.

1. A switch operable under high-voltage and high-power, comprising: a P-type diamond layer doped with an acceptor material; an N-type diamond region doped with a donor material, wherein the N-type diamond region is in contact with the P-type diamond layer; a light blocking layer comprising one or more apertures configured to allow illumination from a light source to pass through to reach the N-type diamond region; a source contact and a drain contact that are at least partially in contact with the P-type diamond layer; and a gate in contact with at least an area of the N-type diamond region, wherein the N-type diamond region, upon receiving the illumination and application of a first bias voltage, is configured to generate a conduction current that remains on in an absence of the illumination.

2. The switch of solution 1, wherein the donor material comprises nitrogen, and wherein the N-type diamond region is doped at a doping level between 1018 to 1019 cm-3.

3. The switch of solution 1 or 2, wherein the acceptor material comprises boron.

4. The switch of any of solutions 1 to 3, wherein a thickness of the P-type diamond layer is between 0.1 um to 10 um.

5. The switch of any of solutions 1 to 4, comprising: an N-type diamond layer in contact with a side of the P-type diamond layer and wherein the gate is in contact with the n-type diamond layer.

6. The switch of any of solutions 1 to 5 further comprising: a passivation layer in contact with the N-type diamond region and the gate.

7. The switch of any of solutions 1 to 6, wherein a photon energy of the illumination is greater than an activation energy of the donor material.

8. The switch of any of solutions 1 to 8, wherein a wavelength of the illumination is smaller than a threshold value that is determined based on characteristics of the donor material.

9. The switch of any of solutions 1 to 8, further comprising: the light source that is configured to emit the illumination at a particular wavelength.

10. The switch of any of solutions 1 to 9, further comprising: a second light source configured to provide additional illumination to excite free holes in the P-type diamond layer, wherein the additional illumination has a greater energy than an activation energy of the acceptor material and a smaller energy than an activation energy of the donor material.

11. A method for operating a switch for a high-voltage and high-power application, comprising: turning a switch to an ON state by applying a bias voltage to a gate of the switch and emitting illumination to an N-type diamond region of the switch via one or more apertures for a predetermined time duration; and turning off or blocking the illumination, wherein the switch comprises a P-type diamond layer doped with an acceptor material, the N-type diamond region doped with a donor material and in contact with the P-type diamond layer, a light blocking layer comprising the one or more apertures configured to allow the illumination of the N-type diamond region, a source contact and a drain contact that are at least partially in contact with the P-type diamond layer, and the gate in contact with at least an area of the N-type diamond region, wherein, in the ON state, a current is established between a source contact and the drain contact; and wherein the switch remains in the ON state when the illumination is blocked or turned off.

12. The method of solution 11, wherein the switch remains in the ON state when the bias voltage is removed.

13. The method of solution 11 or 12, comprising: turning the switch to an OFF state by resuming illumination of the N-type diamond region and adjusting the bias voltage; and tuning off or blocking the illumination, wherein, in the OFF state, no current is established between the source contact and the drain contact.

14. The method of solution 13, wherein the switch remains in the OFF state when the illumination is blocked or turned off.

15. The method of any of solutions 1 to 14, wherein the switch is configured to remain in the ON state for a time duration that is determined based on material properties of the switch.

16. The method of any of solutions 1 to 15, wherein the illumination comprises a pulse having a cycle time between 0.01 to 10 μs.

17. The method of any of solutions 1 to 16, wherein a photon energy of the illumination is greater than an activation energy of the donor material.

18. The method of any of solutions 1 to 17, wherein a wavelength of the illumination is smaller than a threshold value that is determined based on characteristics of the donor material.

19. The method of any of solutions 1 to 18, further comprising: operating a second light source to provide additional illumination to excite free holes in the P-type diamond layer of the switch, wherein a photon energy of the additional illumination is greater than an activation energy of the acceptor material and smaller than an activation energy of the donor material.

20. The method of any of solutions 1 to 19, comprising: applying a drain-to-source bias voltage prior to emitting the illumination.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few implementations and examples are described, and other implementations, enhancements and variations can be made based on what is described and illustrated in this patent document.

What is claimed is:

1. A switch operable under high-voltage and high-power, comprising:
a P-type diamond layer doped with an acceptor material;
an N-type diamond region doped with a donor material, wherein the N-type diamond region is in contact with the P-type diamond layer;
a light blocking layer comprising one or more apertures configured to allow illumination from a light source to pass through to reach the N-type diamond region;
a source contact and a drain contact that are at least partially in contact with the P-type diamond layer; and
a gate in contact with at least an area of the N-type diamond region, wherein the N-type diamond region, upon receiving the illumination and application of a first bias voltage, is configured to generate a conduction current that remains on in an absence of the illumination.

2. The switch of claim 1, wherein the donor material comprises nitrogen, and wherein the N-type diamond region is doped at a doping level between 10¹⁸ to 10¹⁹ cm⁻³.

3. The switch of claim 1, wherein the acceptor material comprises boron.

4. The switch of claim 1, wherein a thickness of the P-type diamond layer is between 0.1 um to 10 um.

5. The switch of claim 1, comprising:
an N-type diamond layer in contact with a side of the P-type diamond layer and wherein the gate is in contact with the n-type diamond layer.

6. The switch of claim 1, further comprising:
a passivation layer in contact with the N-type diamond region and the gate.

7. The switch of claim 1, wherein a photon energy of the illumination is greater than an activation energy of the donor material.

8. The switch of claim 1, wherein a wavelength of the illumination is smaller than a threshold value that is determined based on characteristics of the donor material.

9. The switch of claim 1, further comprising:
the light source that is configured to emit the illumination at a particular wavelength.

10. The switch of claim 1, further comprising:
a second light source configured to provide additional illumination to excite free holes in the P-type diamond layer, wherein the additional illumination has a greater energy than an activation energy of the acceptor material and a smaller energy than an activation energy of the donor material.

11. A method for operating a switch for a high-voltage and high-power application, comprising:
turning a switch to an ON state by applying a bias voltage to a gate of the switch and emitting illumination to an N-type diamond region of the switch via one or more apertures for a predetermined time duration; and
turning off or blocking the illumination,
wherein the switch comprises a P-type diamond layer doped with an acceptor material, the N-type diamond region doped with a donor material and in contact with the P-type diamond layer, a light blocking layer comprising the one or more apertures configured to allow the illumination of the N-type diamond region, a source contact and a drain contact that are at least partially in contact with the P-type diamond layer, and the gate in contact with at least an area of the N-type diamond region,
wherein, in the ON state, a current is established between a source contact and the drain contact; and
wherein the switch remains in the ON state when the illumination is blocked or turned off.

12. The method of claim 11, wherein the switch remains in the ON state when the bias voltage is removed.

13. The method of claim 11, comprising:
turning the switch to an OFF state by resuming illumination of the N-type diamond region and adjusting the bias voltage; and
tuning off or blocking the illumination,
wherein, in the OFF state, no current is established between the source contact and the drain contact.

14. The method of claim 13, wherein the switch remains in the OFF state when the illumination is blocked or turned off.

15. The method of claim 11, wherein the switch is configured to remain in the ON state for a time duration that is determined based on material properties of the switch.

16. The method of claim 11, wherein the illumination comprises a pulse having a cycle time between 0.01 to 10 μs.

17. The method of claim 11, wherein a photon energy of the illumination is greater than an activation energy of the donor material.

18. The method of claim 11, wherein a wavelength of the illumination is smaller than a threshold value that is determined based on characteristics of the donor material.

19. The method of claim 11, further comprising:
operating a second light source to provide additional illumination to excite free holes in the P-type diamond layer of the switch, wherein a photon energy of the additional illumination is greater than an activation energy of the acceptor material and smaller than an activation energy of the donor material.

20. The method of claim 11, comprising:
applying a drain-to-source bias voltage prior to emitting the illumination.
